(19) United States
(12) Patent Application Publication
(10) Pub. No.: US 2005/0284513 A1
(43) Pub. Date: Dec. 29, 2005

(54) Chip card comprising an integrated energy converter

(76) Inventor: Christoph Brabec, Linz (AT)

Correspondence Address: FISH & RICHARDSON PC, P.O. BOX 1022, MINNEAPOLIS, MN, 55440-1022, US

(21) Appl. No.: 10/522,862

(22) PCT Filed: Jul. 22, 2003
(86) PCT No.: PCT/DE03/02463

§ 371 Date: Sep. 6, 2005

(30) Foreign Application Priority Data
Aug. 8, 2002 (DE) 102-36-468-8

(51) Int. Cl. H01L 25/00

(52) U.S. Cl. 136/243

(57) ABSTRACT

The invention relates to a chip card comprising an integrated energy supply. The energy converter is in particular a solar cell, preferably a polymer solar cell.

The invention relates to a chip card, particularly chip cards that have controllable functions influenceable by a user or by changes in environmental conditions and that need an integrated energy supply.

Chips, particularly intelligent chip cards, are being used increasingly in all areas of daily life. For example, all types of cards, such as credit cards and security cards, etc., increasingly store data that are or are becoming retrievable and/or modifiable.

For functionalities to be operated repeatedly on chip cards that have “low information” data storage and/or integrated transponder or display units, an energy supply for these elements is a necessity.

There is currently no suitable energy supply for these cards that is consistent with their low price and plastic production technology.

The object of the invention is, therefore, a chip card comprising an energy supply that is inexpensive and/or can be integrated into the production process of the chip card.

The invention is directed to a chip card comprising an energy converter that occupies either a portion or the entire surface area of the chip card, so that the energy supply of the chip card is integratedly present on said chip card.

Polymer solar cells or “organic solar cells” can be made at low cost by common printing processes (or, more expensively, by PVD processes) on many substrates, including transparent or semitransparent sheets. The solar cells themselves can be produced as completely absorbing or semitransparent.

A polymer solar cell thus fulfills all the requirements for integration into a chip card. In particular, the polymer solar cell is very flexible as regards its integration, since it can be applied opaquely to the unprinted subareas of the chip card and semitransparently to the subareas that are printed. It can also be applied to a transparent substrate on the chip card, e.g. by lamination, etc.

Semitransparent [noun missing] are known from German patent application 101 40 991 (=2001 P 15488 DE).

The terms “polymer” in “polymer solar cell,” “organic material,” and “functional polymer” herein encompass all types of organic, metalorganic and/or organic/inorganic synthetics and composites (hybrids) that are photovoltaically active. They signify, for example, all those denoted in English by terms such as “plastics.” This includes all types of materials except for the semiconductors that form conventional diodes (germanium, silicon) and typical metallic conductors. Hence, there is no intended limitation in the dogmatic sense to organic material as carbon-containing material, but rather, the broadest use of silicones, for example, is also contemplated. Furthermore, the terms are not intended to be subject to any limitation with respect to molecular size, particularly to polymeric and/or oligomeric materials, but instead the use of “small molecules” is completely feasible as well. The word “polymer” in “functional polymer” is historically derived and makes no statement as to the presence of any actual polymeric compound. “Functional polymers” can mean semiconducting, conducting and/or insulating materials.

An energy converter can be applied to the chip card on one side or two sides and over the entire side or only in subareas. For instance, one embodiment of the chip card can carry an energy converter on only the back side. The energy converter, e.g. the polymer solar cell, can also be applied semitransparently or opaquely to the front side or in subareas of the front side of the chip card.

In particular, the polymer solar cell can also be disposed semitransparently over an existing display unit of a chip card (e-paper display; LCDs, OLED display, etc.).

Due to the ability to make a polymer solar cell out of photovoltaically active dyes/functional polymers, a chip card can be printed and inscribed with a polymer solar cell instead of printing ink. For example, logos, images or text can be produced on the chip card by means of polymer solar cells.

The production of the energy converter can be integrated directly into the printing process used to make the chip card, for example when the energy converter is a polymer solar cell that is made by the same printing process for organic functional polymers as the chip card itself.

The energy converter can likewise be produced separately on a substrate, which is then mounted, i.e., for example, laminated, onto the chip card along with the energy converter.

The invention relates to a chip, particularly a chip card comprising an integrated energy supply. The energy converter is in particular a solar cell, preferably a polymer solar cell.

1. A chip card comprising an energy converter that occupies either a portion or an entire surface area of the chip card, so that an energy supply of the chip card is integratedly present thereon.

2. The chip card as defined in claim 1, wherein the energy converter is a photovoltaic cell.

3. The chip card as defined in claim 2, wherein the photovoltaic cell is a polymer solar cell.

4. The chip card as defined in claim 1, wherein the energy converter covers the back side and/or the front side and/or subareas of one of the sides of the chip card.

5. The chip card as defined in claim 1, wherein the energy converter is semitransparent.

6. The chip card as recited in claim 1, wherein the energy converter is colored and/or opaque.

7. The chip card as defined in claim 1, wherein the energy converter is applied over a display unit of the chip card.

8. The chip card as defined in claim 1, wherein the energy converter is producible directly on the chip card.

9. An article, comprising:
a chip card having a surface; and
a photovoltaic cell supported by at least a portion of the surface of the chip card.

10. The article of claim 9, wherein the photovoltaic cell is capable of acting as an energy supply for the chip card.

11. The article of claim 9, wherein the photovoltaic cell is a solar cell.

12. The article of claim 9, wherein the photovoltaic cell is a polymer solar cell.

13. The article of claim 9, wherein the photovoltaic cell is integral with the chip card.

14. The article of claim 9, wherein the photovoltaic cell is printed on the chip card.

15. The article of claim 9, wherein the photovoltaic cell is semitransparent or transparent.

16. The article of claim 9, wherein the photovoltaic cell is colored.

17. The article of claim 9, wherein the photovoltaic cell is opaque.

18. The article of claim 9, further comprising a display unit.

19. The article of claim 18, wherein the photovoltaic cell is supported by the display unit.

20. The article of claim 9, wherein the chip card is selected from the group consisting of credit cards and security cards.
